(19) United States
(12) Patent Application Publication
(10) Pub. No.: US 2010/0032550 A1
(43) Pub. Date: Feb. 11, 2010

(54) IMAGE SENSOR AND METHOD OF MANUFACTURING THE SAME

(76) Inventor: Young Je Yun, Gyeonggi-do (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/510,331

(22) Filed: Jul. 28, 2009

(30) Foreign Application Priority Data
Aug. 6, 2008 (KR) 10-2008-0076943

(51) Int. Cl. H01L 27/00; C23C 14/04

(52) U.S. Cl. 250/208.1; 427/526

(57) ABSTRACT

Disclosed are embodiments of an image sensor and a method of manufacturing the same. The image sensor includes an insulating layer on a substrate, and a graded-index microlens in the insulating layer corresponding to each pixel of the image sensor.

### CROSS-REFERENCE TO RELATED APPLICATION

This application claims the benefit under 35 U.S.C. §119 of Korean Patent Application No. 10-2008-0076943, filed Aug. 6, 2008, which is hereby incorporated by reference in its entirety.

### BACKGROUND

In the conventional technology, processes of forming a color filter array (CFA) and a microlens (ML) are important factors to determine the performance of an image sensor.

According to the representative conventional process of forming the ML, a pattern is formed at a lens area through a lithography process by using an organic material, such as a photoresist (PR) that can be thermally reflowed, and then the resultant structure is subject to the thermal reflow process, thereby forming a spherical surface. Then, the spherical surface is cooled so that the ML can be formed.

When the ML is formed through the above method, since the width of an ML gap is determined by a gap of the pattern formed through the photolithography process before the reflow process is performed, the minimum critical dimension (CD) of the ML gap is restricted to about 50 nm due to the resolution limitation of the lithography process. In addition, if the ML gap is narrowed to about 50 nm or less by excessively performing the reflow process, since neighboring lenses may be mixed with each other or a lens bridge may be created between the neighboring lenses during the reflow process, a zero-gap is effectively impossible.

This lens bridge phenomenon is caused by a mixing phenomenon occurring when PR for a lens having a physically hydrophobic property makes contact with a neighboring lens in a fluid state, that is, when hydrophobic materials make contact with each other in a fluid state. This is similar to a phenomenon in which two drops of water on a glass window make contact with each other to form one drop of water.

Since the PR for a lens has predetermined viscosity in a fluid state, the PR makes a smoothly curved surface and can cause a lens bridge.

In order to reduce a probability of the lens mixing phenomenon or the lens bridge, a dual ML process has been developed, in which lenses arranged in the form of a checker board may cross each other twice. Since the dual ML process is complex and requires precise adjustment of an overlap position of the MLs, the process margin is very small. As described above, the ML process of forming a spherical structure has problems related to the process margin. Accordingly, a complex additional process is required to solve the margin problems.

### BRIEF SUMMARY

The subject disclosure provides an image sensor including a graded index microlens and a method of manufacturing the same, capable of forming a microlens array by using a new material and a new method without actually forming a spherical lens structure.

According to an embodiment, the image sensor includes an insulating layer on a substrate, and a graded-index microlens on the insulating layer corresponding to each pixel.

According to an embodiment, in the method of manufacturing the image sensor, an insulating layer is formed on a substrate, an ion implantation area is formed on the insulating layer corresponding to each pixel, and a graded index microlens is formed by performing an annealing process with respect to the ion implantation area.

### BRIEF DESCRIPTION OF THE DRAWINGS

FIG. 1 is a cross-sectional view showing an image sensor according to an embodiment; and

FIGS. 2 to 7 are cross-sectional views showing a method of manufacturing the image sensor according to an embodiment.

### DETAILED DESCRIPTION

Hereinafter, embodiments of an image sensor and a method of manufacturing the same will be described with reference to accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

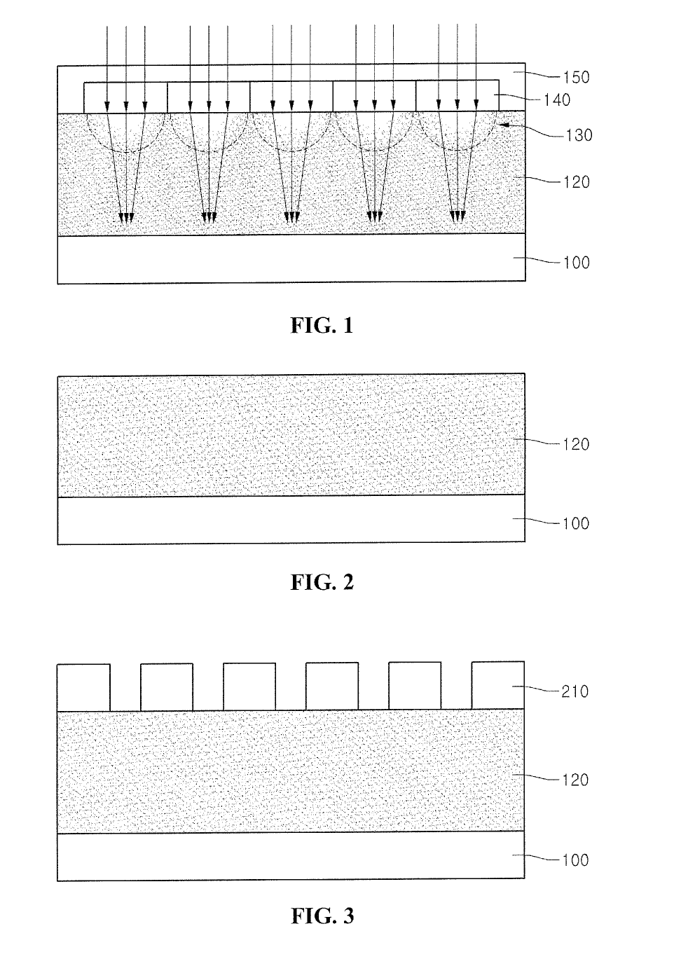

FIG. 1 is a cross-sectional view showing an image sensor according to an embodiment.

The image sensor according to an embodiment includes an insulating layer 120 formed on a substrate 100 and a graded index microlens 130 formed in the insulating layer 120 corresponding to each pixel.

In the image sensor, a gapless microlens array can be formed using a new material and a new method without forming a spherical lens structure. In other words, according to an embodiment, a patterning process and an implantation & annealing process are adjusted to more easily form the gapless microlens array.

Reference numerals of FIG. 1, which have not been described, will be described with respect to a method of manufacturing the image sensor.

Hereinafter, a method of manufacturing an image sensor according to an embodiment will be described with reference to FIGS. 2 to 8.

As shown in FIG. 2, an insulating layer 120 is formed on a substrate 100. The substrate 100 may have been provided with an image sensitive part (not shown). The image sensitive part may be a photodiode, but embodiments are not limited thereto. For example, the image sensitive part may be a photogate or the combination of the photogate and a photodiode.

The image sensitive part may be formed in a horizontal plane (horizontally arranged) with a read-out circuit or formed above the read-out circuit in a vertical arrangement.

The insulating layer 120 may be an oxide layer, but embodiments are not limited thereto. According to certain embodiments, the insulating layer 120 may be a transparent insulating layer through which light can pass.

Next, as shown in FIG. 3, a pattern array 210 having narrow openings corresponding to pixels may be formed.

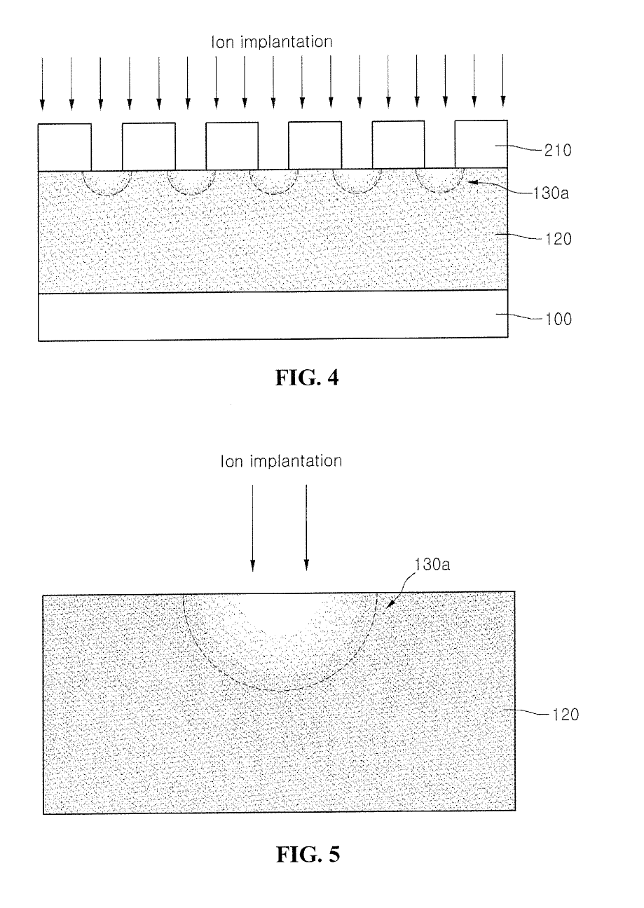

Thereafter, as shown in FIG. 4, an ion implantation area 130a is formed in the insulating layer 120 corresponding to each pixel by using the pattern array 210 as an ion implantation mask. For example, ions such as zinc and boron may be implanted at dose of about 1×10¹⁴ atoms/cm² to about 1×10¹⁶ atoms/cm².

The graded index ion implantation area 130a may be formed through the ion implantation process.

FIG. 5 shows a view showing the graded index ion implantation area 130a in detail.

Hereinafter, a graded index method applied to the embodiment will be described. As shown in FIG. 5, if ions are implanted into an inorganic material, a refractive coefficient is locally increased only in an area into which the ions are implanted. Such phenomenon becomes severe as the mass of the implanted ions is increased.

In the ion implantation structure, as the concentration profile of the ions is gradually changed, the refractive coefficient is gradually changed. Accordingly, the refractive coefficient is expressed as a graded index.

As shown in FIG. 5, the insulating layer 120 represents an inorganic material insulating layer, and the white color of the graded index ion implantation area 130a represents the concentration of implanted ions. The refractive coefficient is increased proportionally to the concentration of the implanted ions. As shown in FIG. 5, in a convex-down pattern, the center of the white color region corresponds to the surface of the insulating layer and represents the greatest refractive coefficient. In addition, the white color is gradually changed into a gray color toward an outer portion of the convex-down pattern and represents that the refractive coefficient is gradually reduced. Accordingly, in the area having the gray color, the refractive coefficient becomes identical to an initial refractive coefficient of the insulating layer 120.

Particularly, according to an embodiment, ions are lightly implanted into a local area of the insulating layer 120, so that the graded index ion implantation area 130a having a convex-down pattern in a hemispherical shape can be formed. Although a conventional graded-index ion implantation area has a cylindrical shape, the graded-index ion implantation area 130a can have a hemispherical shape according to the present embodiment such that the graded-index ion implantation area 130a can be used in a microlens of the image sensor.

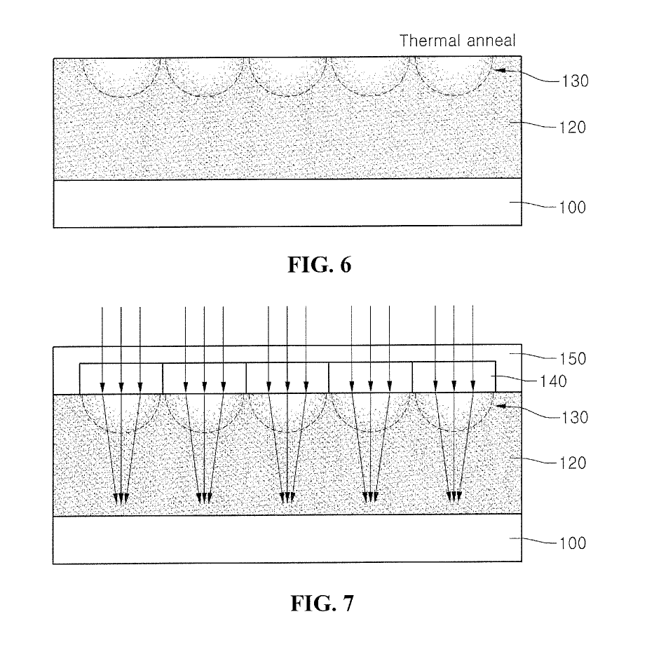

Next, as shown in FIG. 6, an annealing process is performed with respect to the graded index ion implantation area 130a, thereby forming a graded index microlens 130. The shape of the graded index microlens 130 can be dependent on the implantation energy of the ions and the annealing process.

For example, if the size of the graded index microlens 130 is adjusted through the annealing process, the graded index microlens 130 having no gap can be obtained.

The annealing process may be performed at a temperature of about 300° C. to about 500° C.

Since the graded index microlens 130 has a great refractive coefficient, the graded index microlens 130 serves as a condensing lens. Accordingly, the graded index microlens 130 can serve in place of the microlens of a typical image sensor.

Next, as shown in FIG. 7, a color filter layer 140 is formed on the graded index microlens 130, and a planarization layer 150 may be formed on the color filter layer 140.

According to an embodiment, a graded index microlens array is formed below the color filter layer 140. This minimizes the distance between the microlens and the image sensitive part, and protects organic materials, such as for the color filter, from being damaged in the annealing process.

According to another embodiment, after the color filter layer 140 has been formed, the graded index microlens 130 may be formed through a graded index microlens array process by depositing a low-temperature oxide layer. In other words, when an inorganic thin film is formed on an organic material such as the color filter layer 140, a deposition temperature must be maintained to the extent that the organic material is not damaged. Accordingly, after a low-temperature oxidation process has been performed, the graded index microlens 140 can be formed through the ion implantation and annealing process.

In the image sensor and the method of manufacturing the same according to certain embodiments, a gapless microlens array can be formed using a new material and a new method without actually forming a spherical lens structure. In other words, according to an embodiment, a patterning process and an ion implantation and annealing process are adjusted, so that the gapless microlens array can be more easily formed.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
an insulating layer on a substrate; and
a graded-index microlens in the insulating layer and corresponding to each pixel of the image sensor.

2. The image sensor of claim 1, wherein the graded index microlens is formed in the insulating layer through an ion-implantation process.

3. The image sensor of claim 2, wherein the graded index microlens has a convex-down pattern having a hemispherical shape, and wherein the concentration of implanted ions in the insulating layer implanted through the ion-implantation process decreases toward an outer portion of the convex-down pattern from a central portion of the convex-down pattern.

4. The image sensor of claim 2, wherein the graded index micro-lens comprises zinc or boron ions.

5. The image sensor of claim 1, wherein the graded index microlens has a convex-down pattern having a hemispherical shape, and wherein a refractive coefficient of the graded index microlens decreases toward an outer portion of the convex-down pattern from a central portion of the convex-down pattern.

6. The image sensor of claim 1, further comprising a color filter layer on the graded-index microlens.

7. The image sensor of claim 1, further comprising a color filter layer between the substrate and the insulating layer having the graded-index microlens therein.

8. A method of manufacturing an image sensor, the method comprising:
forming an insulating layer on a substrate;
forming an ion implantation area on the insulating layer corresponding to each pixel of the image sensor; and
forming a graded index microlens by performing an annealing process with respect to the ion implantation area.

9. The method of claim 8, further comprising:
forming a color filter layer on the graded index microlens after forming the graded index microlens.

10. The method of claim 8, further comprising:
forming a color filter layer on the substrate before forming the ion implantation area in the insulating layer corresponding to each pixel.

11. The method of claim 10, wherein the insulating layer is formed on the color filter layer by using a low-temperature oxide.

12. The method of claim 8, wherein the graded index microlens has a convex-down pattern having a hemispherical shape, and wherein the concentration of ions of the ion-implantation area decreases toward an outer portion of the convex-down pattern from a central portion of the convex-down pattern.

13. The method of claim 8, wherein the graded index microlens has a convex-down pattern having a hemispherical shape, and wherein a refractive coefficient of the graded index microlens decreases toward an outer portion of the convex-down pattern from a central portion of the convex-down pattern.

14. The method of claim 8, wherein the forming of the ion implantation area comprises implanting zinc or boron ions into the insulating layer.
